(19) United States
(12) Patent Application Publication
(10) Pub. No.: US 2009/0014818 A1
(43) Pub. Date: Jan. 15, 2009

(54) SEMICONDUCTOR DEVICE AND MANUFACTURING METHOD THEREOF

(76) Inventor: Akiko NOMACHI, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/169,166

(22) Filed: Jul. 8, 2008

(30) Foreign Application Priority Data
Jul. 9, 2007 (JP) 2007-180017

(51) Int. Cl. H01L 29/78; H01L 21/28

(52) U.S. Cl. 257/412; 438/595; 257/E29.255; 257/E21.177

(57) ABSTRACT

A semiconductor device includes a semiconductor substrate, a gate insulating film formed on the semiconductor substrate, a gate electrode formed on the gate insulating film, a first insulating film formed on a side surface of the gate electrode, a second insulating film covering a surface of the first insulating film and formed of a material different from a material of the first insulating film, and a third insulating film covering the semiconductor substrate, the gate electrode and the second insulating film and formed of a material different from the material of the second insulating film.

### CROSS-REFERENCE TO RELATED APPLICATIONS

This application is based upon and claims the benefit of priority from prior Japanese Patent Application No. 2007-180017, filed Jul. 9, 2007, the entire contents of which are incorporated herein by reference.

### BACKGROUND OF THE INVENTION

1. Field of the Invention

The present invention relates to a semiconductor device and a manufacturing method thereof.

2. Description of the Related Art

Recently, a full silicide gate structure in which an entire gate electrode is formed of silicide has been proposed from the perspective of enhanced performance of a MIS transistor (e.g., refer to Jpn. Pat. Appln. KOKAI Publication No. 2006-332270). In this MIS transistor having the full silicide gate structure, a silicon nitride film is used as a sidewall insulating film of the gate electrode at the request of a manufacturing process.

However, when the silicon nitride film is used as the sidewall insulating film of the gate electrode, the sidewall insulating film (silicon nitride film) might be etched in, for example, a contact hole forming step. As a result, a part of a semiconductor substrate under the sidewall insulating film is etched together, which causes deterioration in the characteristics and reliability of the MIS transistor.

Therefore, effectively preventing the etching of the sidewall insulating film of the gate electrode is important in obtaining a semiconductor device with good characteristics and reliability.

### BRIEF SUMMARY OF THE INVENTION

A first aspect of the present invention, there is provided a semiconductor device comprising: a semiconductor substrate; a gate insulating film formed on the semiconductor substrate; a gate electrode formed on the gate insulating film; a first insulating film formed on a side surface of the gate electrode; a second insulating film covering a surface of the first insulating film and formed of a material different from a material of the first insulating film; and a third insulating film covering the semiconductor substrate, the gate electrode and the second insulating film and formed of a material different from the material of the second insulating film.

A second aspect of the present invention, there is provided a semiconductor device manufacturing method comprising: forming a structure which includes a gate insulating film formed on a semiconductor substrate, a gate electrode formed on the gate insulating film, a first insulating film formed on a side surface of the gate electrode, and a second insulating film covering a surface of the first insulating film and formed of a material different from a material of the first insulating film; forming a third insulating film covering the semiconductor substrate, the gate electrode and the second insulating film and formed of a material different from the material of the second insulating film; forming a fourth insulating film covering the third insulating film and formed of a material different from the material of the third insulating film; and forming a contact hole in the third insulating film and the fourth insulating film.

A third aspect of the present invention, there is provided a semiconductor device manufacturing method comprising: forming a structure which includes a gate insulating film formed on a silicon substrate, a silicon film formed on the gate insulating film, a first silicon nitride film formed on an upper surface of the silicon film, and a second silicon nitride film formed on a side surface of the silicon film; converting a surface region of the silicon substrate which is not covered with the structure to a first silicide film; forming a first silicon oxide film on the first silicide film; removing the first silicon nitride film to expose the silicon film after forming the first silicon oxide film; converting the exposed silicon film to a second silicide film to form a gate electrode; removing the first silicon oxide film after forming the gate electrode; forming a second silicon oxide film covering a surface of the second silicon nitride film after removing the first silicon oxide film; forming a third silicon nitride film covering the first silicide film, the gate electrode and the second silicon oxide film; forming a third silicon oxide film covering the third silicon nitride film; forming a preliminary hole reaching the third silicon nitride film in the third silicon oxide film; and removing that part of the third silicon nitride film which is located under the preliminary hole to form a contact hole in the third silicon oxide film and the third silicon nitride film.

### BRIEF DESCRIPTION OF THE SEVERAL VIEWS OF THE DRAWING

FIG. 1 to FIG. 11 are sectional views schematically showing a process of manufacturing a semiconductor device according to an embodiment of the present invention; and

FIG. 12 to FIG. 14 are sectional views schematically showing a process of manufacturing a semiconductor device according to a comparative example of the embodiment of the present invention.

### DETAILED DESCRIPTION OF THE INVENTION

Hereinafter, an embodiment of the present invention will be described with reference to the drawings.

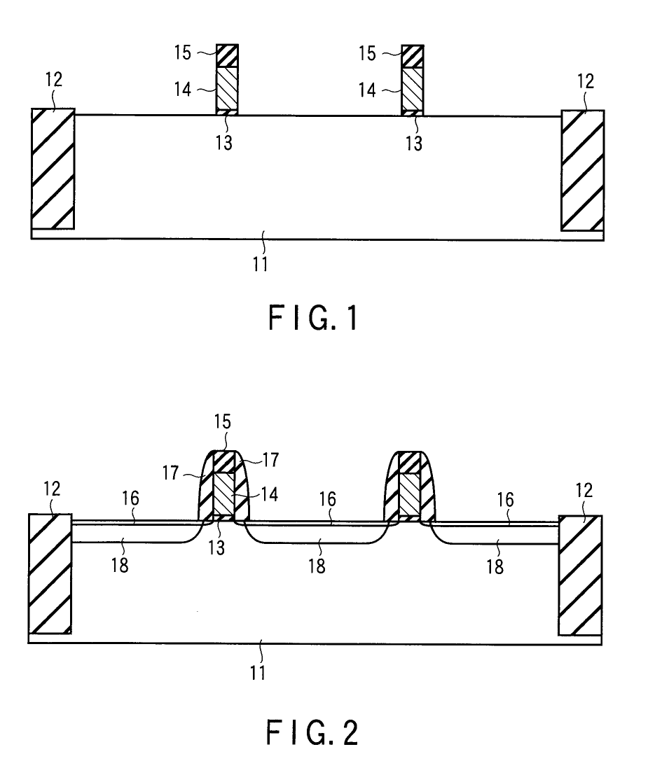

FIG. 1 to FIG. 11 are sectional views schematically showing a process of manufacturing a semiconductor device (semiconductor integrated circuit device) according to the embodiment of the present invention.

First, as shown in FIG. 1, a shallow trench isolation (STI) type isolation region 12 is formed in a silicon substrate (semiconductor substrate) 11. Then, a gate insulating film 13 is formed on the silicon substrate 11, and a polysilicon film 14 having a thickness of 100 nm is formed on the gate insulating film 13. Further, a silicon nitride film (first silicon nitride film) 15 having a thickness of 50 nm is formed on the polysilicon film 14. Then, the silicon nitride film 15, the polysilicon film 14 and the gate insulating film 13 are patterned.

Then, as shown in FIG. 2, a structure (structure formed by the gate insulating film 13, the polysilicon film 14 and the silicon nitride film 15) obtained by the patterning is used as a mask to carry out ion implantation of impurities (n-type or p-type impurities) into the silicon substrate 11, thereby forming an extension diffusion layer 16. Then, a silicon nitride film (second silicon nitride film) 17 is formed as a sidewall insulating film on the sidewall of the structure obtained by the patterning. Further, the silicon nitride film 17 is used as a mask to carry out ion implantation of impurities (n-type or p-type impurities) into the silicon substrate 11, thereby forming a source/drain diffusion layer 18.

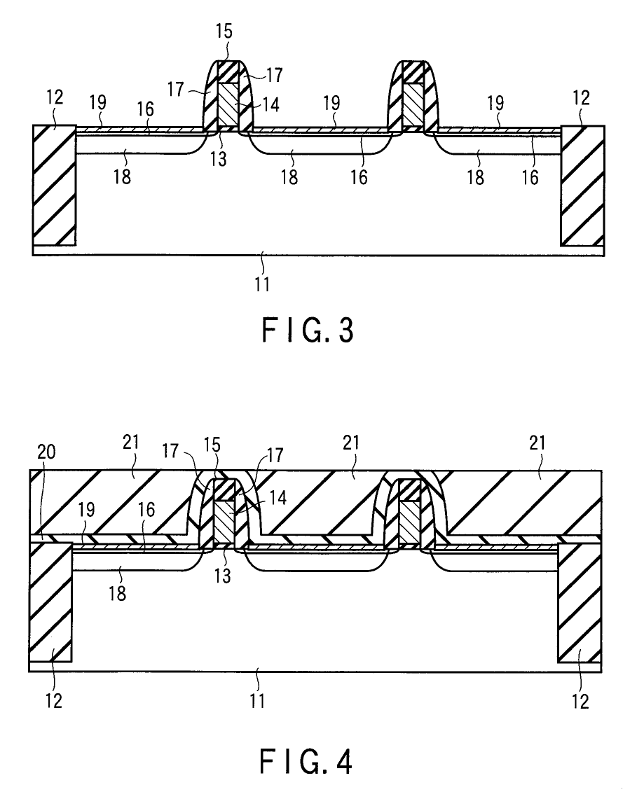

Then, as shown in FIG. 3, a surface region of the silicon substrate 11 which is not covered with the structure obtained by the step in FIG. 2 is converted to a silicide film (first silicide film) 19. Specifically, after deposition of a metal film of nickel or the like over the entire surface, a reaction is caused between the exposed surface of the silicon substrate 11 and the metal film by a thermal treatment. Thus, the surface region of the silicon substrate 11 is silicidated, and the silicide film 19 is formed. Here, a nickel silicide film having a thickness of 20 nm is formed. In addition, as the polysilicon film 14 is covered with the silicon nitride films 15 and 17, the polysilicon film 14 is not converted to a silicide film.

Then, as shown in FIG. 4, a silicon nitride film 20 having a thickness of about 20 nm is deposited over the entire surface by chemical vapor deposition (CVD). Then, a silicon oxide film (first silicon oxide film) 21 having a thickness of about 300 nm is deposited on the silicon nitride film 20 by the CVD. Further, the silicon oxide film 21 is planarized by chemical mechanical polishing (CMP). In accordance with the present process, a structure in which the silicide film 19 is covered with the silicon nitride film 20 and the silicon oxide film 21 is obtained.

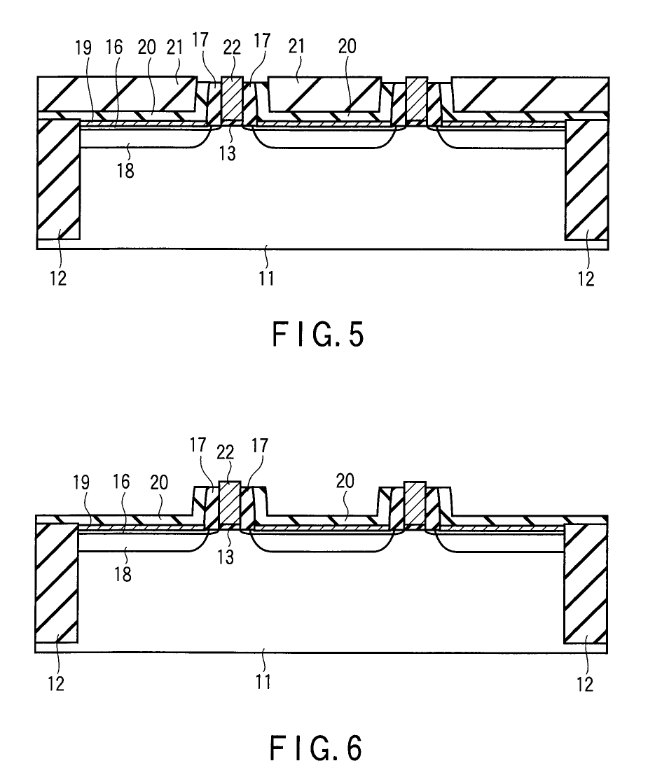

Then, as shown in FIG. 5, the silicon nitride films 15, 17 and 20 as well as the silicon oxide film 21 are etched by a dry etching technique. As a result, the silicon nitride film 15 is removed, and the polysilicon film 14 is exposed. Then, the exposed polysilicon film 14 is entirely converted to a silicide film (second silicide film) 22. A gate electrode (full silicide gate electrode) is formed by this silicide film 22. Specifically, after deposition of a metal film of nickel or the like over the entire surface, a reaction is caused between the polysilicon film 14 and the metal film by a thermal treatment. Thus, the entire polysilicon film 14 is silicidated, and the silicide film 22 is formed. Here, a nickel silicide film is formed. In addition, as the surface of the silicon substrate 11 is covered with the silicon nitride film 20 and the silicon oxide film 21, no new silicide film is formed on the surface of the silicon substrate 11.

Then, as shown in FIG. 6, the silicon oxide film 21 is selectively removed with respect to the silicon nitride films 17 and 20 by dry etching. Given that a silicon oxide film is used instead of the silicon nitride film 17 as the sidewall insulating film at this point, the sidewall insulating film is etched together when the silicon oxide film 21 is etched. As a result, a part of the silicon substrate 11 under the sidewall insulating film might be etched together, which causes deterioration in the characteristics and reliability of a MIS transistor. It is therefore necessary to use the silicon nitride film 17 for the sidewall insulating film.

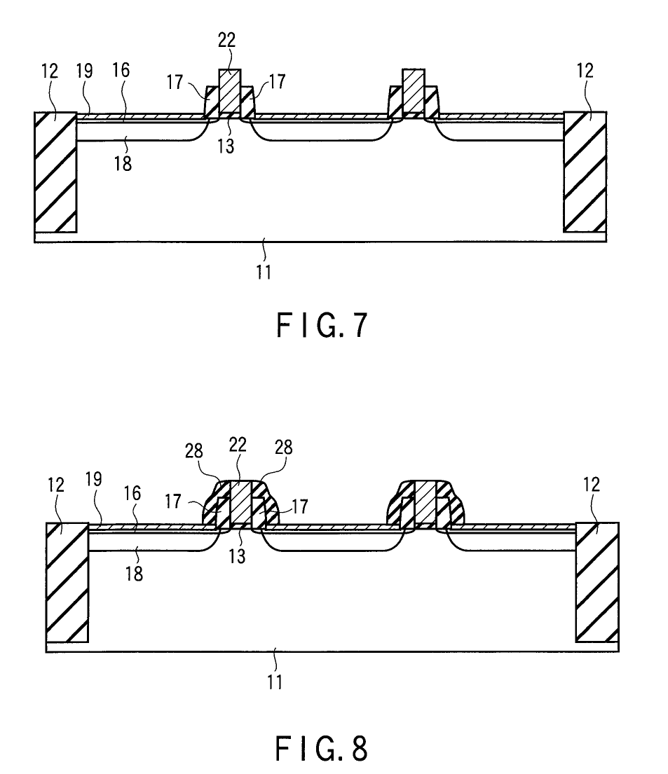

Then, as shown in FIG. 7, the silicon nitride film 20 is selectively etched and removed with respect to the silicon substrate 11, the isolation region 12, and the silicide films 19 and 22. At this point, the silicon nitride film 17 is etched together, and the height of the silicon nitride film 17 decreases. For example, the height of the silicon nitride film 17 becomes about 50 nm lower than the height of the gate electrode (silicide film) 22.

Here, a comparative example of the present embodiment is described.

In the comparative example, as shown in FIG. 12, a silicon nitride film 23 having a thickness of 50 nm is formed over the entire surface after the step in FIG. 7. This silicon nitride film 23 functions as an etching stopper in a contact hole forming step. The silicon nitride film 23 also functions as a stress generating film for applying strain to a channel region of the silicon substrate 11. The application of the strain to the channel region makes it possible to increase carrier mobility. Then, a silicon oxide film 24 is formed as an interlayer insulating film on the silicon nitride film 23, and the silicon oxide film 24 is planarized. The thickness of the silicon oxide film 24 after the planarization is about 300 nm in a region on the gate electrode 22 and about 400 nm in other regions.

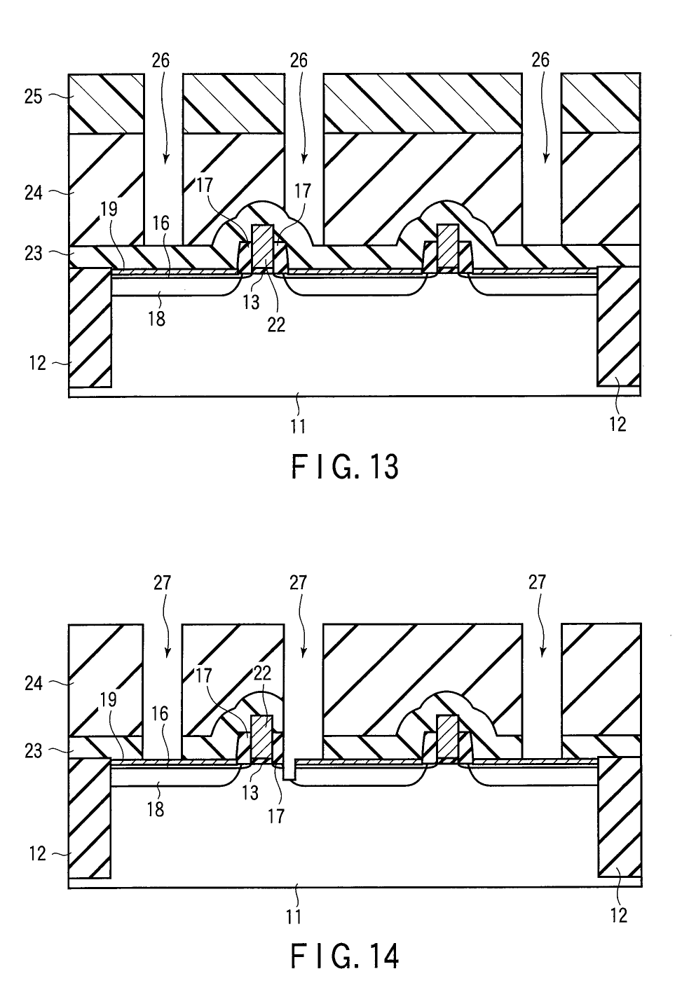

Then, as shown in FIG. 13, a photoresist pattern 25 for contact hole formation is formed on the silicon oxide film 24 by photolithography. Then, the photoresist pattern 25 is used as a mask to selectively etch the silicon oxide film 24 with respect to the silicon nitride film 23. That is, when the silicon oxide film 24 is etched, the silicon nitride film 23 functions as the etching stopper. Thus, a preliminary hole 26 reaching the silicon nitride film 23 is formed in the silicon oxide film 24.

Then, as shown in FIG. 14, a part of the silicon nitride film 23 located under the preliminary hole 26 is etched and removed. Thus, a contact hole 27 reaching the silicide film 19 is formed in the silicon oxide film 24 and the silicon nitride film 23.

However, the comparative example described above contains the following problem. That is, if the contact hole 27 is displaced from an ideal position, the silicon nitride film 17 on the sidewall of the gate electrode 22 is etched together when the silicon nitride film 23 is etched, as shown in FIG. 14. As a result, a part of the silicon substrate 11 under the silicon nitride film 17 might be etched together, which may be a major cause of deterioration in the characteristics and reliability of the MIS transistor.

Therefore, the present embodiment uses the following method to prevent the above-mentioned problem.

In the present embodiment, as shown in FIG. 8, a silicon oxide film is formed over the entire surface by the CVD after the step in FIG. 7, and the gate electrode 22 and the silicon nitride film (first insulating film) 17 are covered by this silicon oxide film. Then, this silicon oxide film is subjected to anisotropic dry etching. Thus, a silicon oxide film (second silicon oxide film, second insulating film) 28 remains on the sidewall of the gate electrode 22. As has already been described, the height of the silicon nitride film 17 is lower than the height of the gate electrode 22. That is, the upper surface (upper end) of the silicon nitride film 17 is located lower the upper surface of the gate electrode 22. Moreover, conditions of the anisotropic dry etching can be optimized so that the height of the upper surface (upper end) of the silicon oxide film 28 may be equal to the height of the upper surface of the gate electrode 22. Therefore, the entire exposed surface of the silicon nitride film 17 can be covered with the silicon oxide film 28. That is, the upper surface and side surface of the silicon nitride film 17 are covered with the silicon oxide film 28. In addition, as the silicide film 19 is already formed before the formation of the silicon oxide film 28, the silicide film 19 is interposed between the silicon substrate 11 and the silicon oxide film 28.

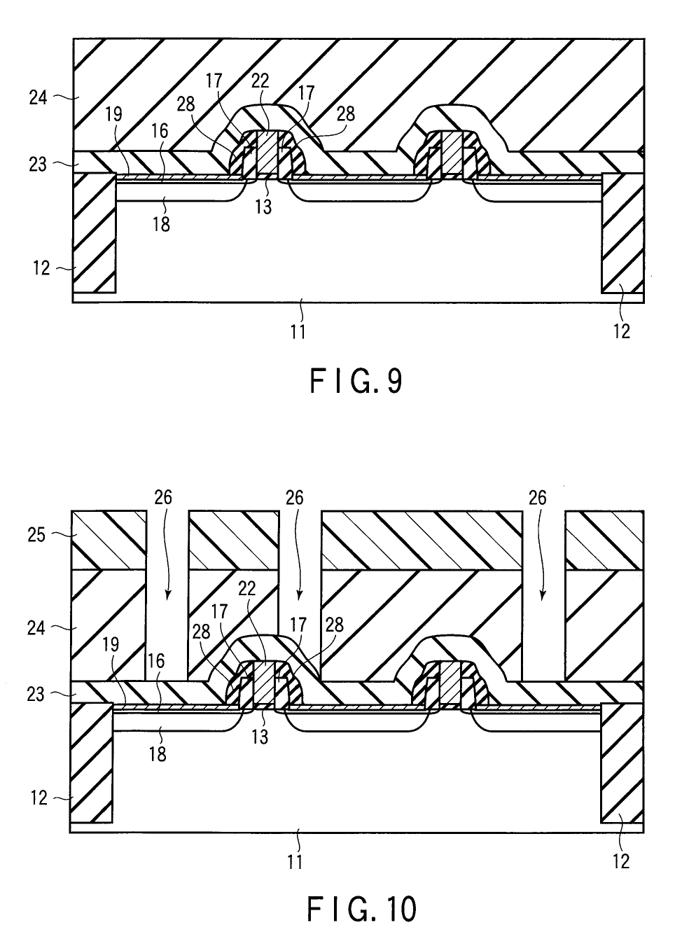

Then, as shown in FIG. 9, the silicon nitride film (third silicon nitride film, third insulating film) 23 having a thickness of 50 nm is formed over the entire surface. The silicide film 19, the gate electrode 22 and the silicon oxide film 28 are covered with this silicon nitride film 23. This silicon nitride film 23 functions as the etching stopper in the contact hole forming step. The silicon nitride film 23 also functions as the stress generating film for applying strain to the channel region of the silicon substrate 11. The application of the strain to the channel region makes it possible to increase carrier mobility. Then, the silicon oxide film (third silicon oxide film, fourth insulating film) 24 is formed as an interlayer insulating film on the silicon nitride film 23, and the silicon oxide film 24 is planarized. The thickness of the silicon oxide film 24 after the planarization is about 300 nm in a region on the gate electrode 22 and about 400 nm in other regions.

Then, as shown in FIG. 10, the photoresist pattern 25 for contact hole formation is formed on the silicon oxide film 24 by photolithography. Then, the photoresist pattern 25 is used as a mask to selectively etch the silicon oxide film 24 with respect to the silicon nitride film 23. That is, when the silicon oxide film 24 is etched, the silicon nitride film 23 functions as the etching stopper. Thus, the preliminary hole 26 reaching the silicon nitride film 23 is formed in the silicon oxide film 24.

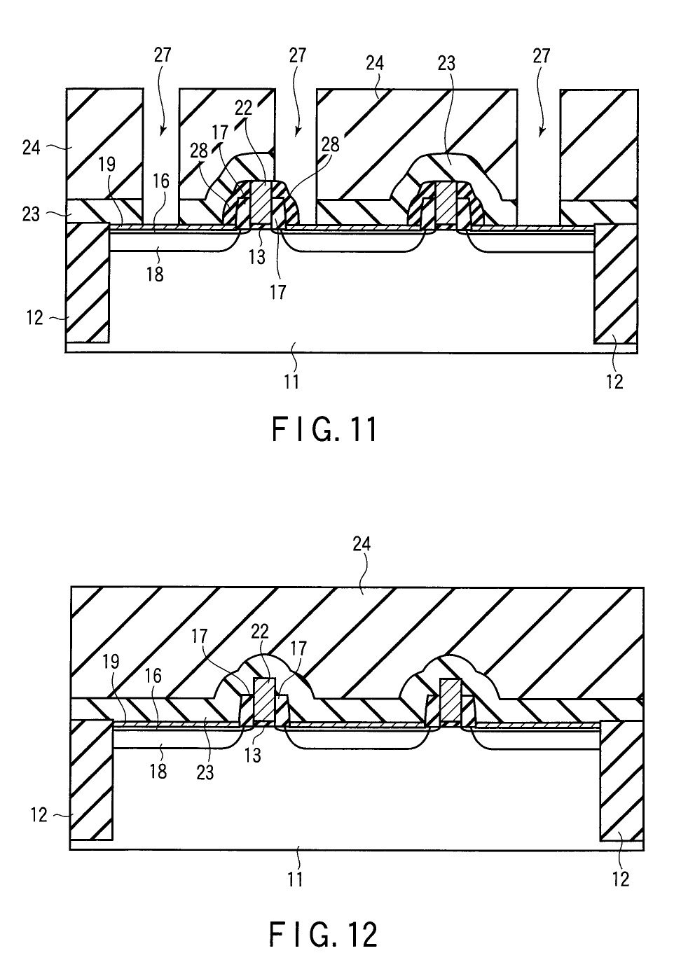

Then, as shown in FIG. 11, a part of the silicon nitride film 23 located under the preliminary hole 26 is etched and removed. The silicon nitride film 23 is selectively etched and removed with respect to the silicide film 19 and the silicon oxide film 28. Thus, the contact hole 27 reaching the silicide film 19 is formed in the silicon oxide film 24 and the silicon nitride film 23.

In the present embodiment, the entire surface of the silicon nitride film 17 is covered with the silicon oxide film 28. That is, the silicon nitride film 17 is protected by the silicon oxide film 28. Thus, as shown in FIG. 11, the etching of the silicon nitride film 17 can be prevented by the silicon oxide film 28 even if the contact hole 27 is displaced from an ideal position. Therefore, the problem of the silicon substrate 11 being etched can be prevented, and the deterioration in the characteristics and reliability of the MIS transistor can be prevented.

Although the subsequent steps are not specifically shown, a contact is formed in the contact hole 27 by a conductor. Further, the semiconductor device (semiconductor integrated circuit device) is completed after a wiring step, etc.

As described above, in the present embodiment, the surface of the silicon nitride film (sidewall insulating film, first insulating film) 17 formed on the sidewall of the gate electrode 22 is covered with the silicon oxide film (second insulating film) 28. Then, the silicon nitride film (third insulating film) 23 is formed to cover the silicon substrate 11, the gate electrode 22 and the silicon oxide film 28, and the silicon oxide film (fourth insulating film) 24 is formed to cover the silicon nitride film 23. Thus, as the surface of the silicon nitride film 17 is covered with the silicon oxide film 28, the silicon nitride film 17 can be protected by the silicon oxide film 28 when the silicon nitride film 23 is etched (e.g., when a contact hole is formed in the silicon nitride film 23 and the silicon oxide film 24). It is therefore possible to prevent the problem of the silicon nitride film 17 being etched to cause the exposure of the surface of the silicon substrate 11. As a result, it is possible to prevent the problem of the silicon substrate 11 being etched to result in deterioration of the characteristics and reliability of the MIS transistor, such that a semiconductor device with good characteristics and reliability can be obtained.

Furthermore, in the present embodiment, the silicon oxide film 28 is formed after the silicide film 19 has been formed. Therefore, the silicide film 19 is interposed between the silicon substrate 11 and the silicon oxide film 28. Thus, the distance between the channel region and the silicide film 19 is regulated by the width of the silicon nitride film 17, and the distance between the channel region and the silicide film 19 can be short. As a result, resistance between the channel region and the silicide film 19 can be reduced, and the characteristics of the MIS transistor can be improved.

In addition, in the embodiment described above, the gate electrode is formed by the silicide film 22, and the silicide film 19 is formed on the source/drain region, but the method of the embodiment described above is also applicable to a structure which does not use the silicide film.

Furthermore, in the embodiment described above, the first insulating film is formed by the silicon nitride film 17, the second insulating film is formed by the silicon oxide film 28, the third insulating film is formed by the silicon nitride film 23, and the fourth insulating film is formed by the silicon oxide film 24. However, insulating films other than the silicon nitride film and the silicon oxide film can be used for the first to fourth insulating films. It is only necessary that the second insulating film is formed by a material different from the material of the first insulating film, that the third insulating film is formed by a material different from the material of the second insulating film, and that the fourth insulating film is formed by a material different from the material of the third insulating film. For example, it is preferable to select the materials of the insulating films so that the third insulating film can be selectively etched with respect to the second insulating film and the fourth insulating film can be selectively etched with respect to the third insulating film. For example, if the third insulating film can be selectively etched with respect to the second insulating film, the first insulating film can be protected by the second insulating film even when the first insulating film and the third insulating film are formed of the material of the same kind.

Still further, in the embodiment described above, an element other than silicon and nitrogen may be added to the silicon nitride film. Moreover, an element other than silicon and oxygen may be added to the silicon oxide film. For example, an element such as phosphorus (P) or boron (B) may be added to the silicon oxide film.

Furthermore, the following modifications can be made of the manufacturing method of the embodiment described above.

A first modification is described. In the embodiment described above, the polysilicon film is used as the film 14, and the polysilicon film is converted to the silicide film to form the gate electrode 22 in the step in FIG. 5. In the present modification, a stack film of a metal film and a polysilicon film on the metal film is used as the film 14. Then, the polysilicon film alone is converted to a silicide film (e.g., a nickel silicide film) in the step in FIG. 5. As a result, the gate electrode 22 in which the metal film and the silicide film are stacked in this order is obtained. Part of the polysilicon film may be converted to a silicide film in the step in FIG. 5. In this case, the gate electrode 22 in which the metal film, the polysilicon film and the silicide film are stacked in this order is obtained. The present modification is similar to the embodiment described above in other basic manufacturing steps.

A second modification is described. In the present modification, a metal film alone is used as the film 14. Then, the gate electrode 22 is formed by this metal film. That is, the gate electrode 22 is formed without converting the film 14 to a silicide film. The present modification is similar to the embodiment described above in other basic manufacturing steps.

A third modification is described. In the present modification, a so-called damascene gate structure is used. In the present modification, the polysilicon film (dummy gate electrode film) 14 is removed to form a trench in the step in FIG. 5. Then, the trench is filled with a metal film to form a gate electrode. When the trench is formed, the gate insulating film (dummy gate insulating film) 13 may be removed in addition to the polysilicon film (dummy gate electrode film) 14. In this case, a new gate insulating film and gate electrode are formed in the trench. The present modification is similar to the embodiment described above in other basic manufacturing steps.

In addition, in the first, second and third modifications described above, it is possible to use, as the metal film for the gate electrode, a TiN film, an Ru film, an RuO film, an NiSi film, a PtTiN film, a TaSiN film, a TaC film, a TaN film, an Mo film, a W film, a WN film, a PtSi film, or a stack film of these films.

Moreover, as the gate insulating film, it is possible to use an SiO film, an SiON film, an HfO film, an HfON film, a ZrO film, a ZrON film, an HfSiO film, an HfSiON film, a ZrSiO film, a ZrSiON film, an HfZrO film, an HfZrON film, an HfZrSiO film, an HfZrSiON film, an HfAlSiON film, a ZrAlSiON film, or a stack film of these films.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
a gate insulating film formed on the semiconductor substrate;
a gate electrode formed on the gate insulating film;
a first insulating film formed on a side surface of the gate electrode;
a second insulating film covering a surface of the first insulating film and formed of a material different from a material of the first insulating film; and
a third insulating film covering the semiconductor substrate, the gate electrode and the second insulating film and formed of a material different from the material of the second insulating film.

2. The semiconductor device according to claim 1, wherein
the third insulating film is formed of the same material as the first insulating film.

3. The semiconductor device according to claim 1, wherein
the first insulating film is formed of a silicon nitride film, the second insulating film is formed of a silicon oxide film, and the third insulating film is formed of a silicon nitride film.

4. The semiconductor device according to claim 1, wherein
an upper end of the first insulating film is located lower than an upper surface of the gate electrode.

5. The semiconductor device according to claim 1, further comprising:
a silicide film formed between the semiconductor substrate and the second insulating film and between the semiconductor substrate and the third insulating film.

6. The semiconductor device according to claim 1, wherein
the gate electrode includes a silicide film.

7. The semiconductor device according to claim 1, further comprising:
a fourth insulating film covering the third insulating film and formed of a material different from the material of the third insulating film.

8. The semiconductor device according to claim 7, wherein
a contact hole is formed in the third insulating film and the fourth insulating film.

9. The semiconductor device according to claim 7, wherein
the first insulating film is formed of a silicon nitride film, the second insulating film is formed of a silicon oxide film, the third insulating film is formed of a silicon nitride film, and the fourth insulating film is formed of a silicon oxide film.

10. A semiconductor device manufacturing method comprising:
forming a structure which includes a gate insulating film formed on a semiconductor substrate, a gate electrode formed on the gate insulating film, a first insulating film formed on a side surface of the gate electrode, and a second insulating film covering a surface of the first insulating film and formed of a material different from a material of the first insulating film;
forming a third insulating film covering the semiconductor substrate, the gate electrode and the second insulating film and formed of a material different from the material of the second insulating film;
forming a fourth insulating film covering the third insulating film and formed of a material different from the material of the third insulating film; and
forming a contact hole in the third insulating film and the fourth insulating film.

11. The method according to claim 10, wherein
the third insulating film is formed of the same material as the first insulating film.

12. The method according to claim 10, wherein
the first insulating film is formed of a silicon nitride film, the second insulating film is formed of a silicon oxide film, and the third insulating film is formed of a silicon nitride film.

13. The method according to claim 12, wherein
the fourth insulating film is formed of a silicon oxide film.

14. The method according to claim 10, wherein
an upper end of the first insulating film is located lower than an upper surface of the gate electrode in said structure.

15. The method according to claim 10, wherein
forming the contact hole in the third insulating film and the fourth insulating film includes:
forming a preliminary hole reaching the third insulating film in the fourth insulating film; and
removing that part of the third insulating film which is located under the preliminary hole.

16. The method according to claim 10, wherein
the third insulating film is capable of being selectively etched with respect to the second insulating film.

17. A semiconductor device manufacturing method comprising:
forming a structure which includes a gate insulating film formed on a silicon substrate, a silicon film formed on the gate insulating film, a first silicon nitride film formed on an upper surface of the silicon film, and a second silicon nitride film formed on a side surface of the silicon film;
converting a surface region of the silicon substrate which is not covered with said structure to a first silicide film;
forming a first silicon oxide film on the first silicide film;
removing the first silicon nitride film to expose the silicon film after forming the first silicon oxide film;
converting the exposed silicon film to a second silicide film to form a gate electrode;
removing the first silicon oxide film after forming the gate electrode;
forming a second silicon oxide film covering a surface of the second silicon nitride film after removing the first silicon oxide film;
forming a third silicon nitride film covering the first silicide film, the gate electrode and the second silicon oxide film;
forming a third silicon oxide film covering the third silicon nitride film;
forming a preliminary hole reaching the third silicon nitride film in the third silicon oxide film; and
removing that part of the third silicon nitride film which is located under the preliminary hole to form a contact hole in the third silicon oxide film and the third silicon nitride film.
